(19) United States
(12) Patent Application Publication
(10) Pub. No.: US 2006/0063305 A1
(43) Pub. Date: Mar. 23, 2006

(54) PROCESS OF FABRICATING FLIP-CHIP PACKAGES

(76) Inventors: Tzu-Chung Wei, Taichung County (TW); Jau-Shoung Chen, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,789

(22) Filed: Sep. 22, 2005

(30) Foreign Application Priority Data
Sep. 22, 2004 (TW) 93128688

(51) Int. Cl. H01L 21/48

(52) U.S. Cl. 438/108

(57) ABSTRACT

A process of fabricating flip-chip packages is disclosed. First, a substrate having a carrying surface is provided. Next, a chip is provided, wherein the chip has an active surface, a plurality of bonding pads are disposed on the active surface and on each bonding pad a bump is disposed. Afterwards, the active surface of the chip is placed to face the carrying surface of the substrate, so that the chip is electrically connected to the substrate via the bumps and a flip-chip package is formed. Further, an underfill is filled between the substrate and the chip to encapsulates the bumps, while the processing temperature is kept between 100° C. and 140° C. for the underfill to be partially cured. Furthermore, the underfill is heated to be fully cured. By means of the process of fabricating flip-chip packages, the material uniformity after curing the underfill is solidly improved.

### CROSS-REFERENCE TO RELATED APPLICATION

This application claims the priority benefit of Taiwan application serial no. 93128688, filed on Sep. 22, 2004. All disclosure of the Taiwan application is incorporated herein by reference.

### BACKGROUND OF THE INVENTION

1. Field of Invention

The present invention relates to a method for forming underfill, and particularly to a method for forming underfill in a process of fabricating flip-chip packages.

2. Description of the Related Art

Along with an increasing and increasing IC (integrated circuit) integrity, diverse chip packaging technologies emerge. In particular, a so-called flip-chip interconnect technology (FC interconnecting) has the most advantage due to a downsized chip package and a shortened signal transmission path thereof and is widely applied in chip packaging field today. Such as chip scale package (CSP), direct chip attached package (DCA package) and multi-chip module package (MCM package), most of the chip packaging can be done by means of flip-chip interconnect technology (FC interconnecting).

Basically, a flip-chip interconnect technology (FC interconnecting) can be described as follows. Bonding pads in array are disposed on an active surface of a chip and then bumps are formed on the bonding pads. Afterwards, the chip is flipped and the bumps on the chip are placed such way to interconnect the same to a plurality of bump pads on a substrate, so that the chip and the substrate are able to mechanically and electrically interconnect to each other and the chip can further be electrically connected to an external electronic device through the internal circuits in the substrate. In addition, since thermal stress between the chip and the substrate could be happened due to unmatched coefficients of thermal expansion (CTE) thereof, an underfill is preferably filled between the chip and the substrate. The underfill encapsulates the bumps to avoid crack caused by a repeatedly action of thermal stress between the chip and the substrate.

FIG. 1 is a schematic sectional view of a conventional flip-chip package. Referring to FIG. 1, a chip 110 is disposed on a substrate 120 in FC interconnecting mode and the active surface 110a of the chip 110 faces a carrying surface 120a of the substrate 120 for disposition. On the active surface 110a of the chip 110, a plurality of bonding pads 112 are disposed. On the carrying surface 120a of the substrate 120, a plurality of bump pads 122 corresponding to the bonding pads 112 are disposed. Each bonding pad 112 is electrically connected to the corresponding bump pad 122 via a corresponding bump 130. In addition, an underfill 140 is filled between the chip 110 and the substrate 120. The underfill 140 encapsulates the bumps 130 and is used for buffering against the possible thermal stress produced between the chip 110 and the substrate 120.

In the prior art, the process to fill underfill is performed after interconnecting the chip 110 to the substrate 120. Before filling the underfill 140, the chip 110 and the substrate 120 are pre-heated. Then, the underfill 140 is filled between the chip 110 and the substrate 120. Once the underfill 140 is filled, the product, i.e. the flip-chip package, is transferred to a holding region to wait for some time. The preset environment temperature in the holding region is around 80° C. for pre-baking the underfill 140. After completely filling the same batch of the products with underfill, the batch of the products is sent to an oven for baking until the underfill 140 is fully cured.

Remarkably, since the preset environment temperature in the holding region specified by the prior art is not high, around 80° C. only, therefore, it is very often to fail the goal that the underfill must be effectively, partially cured during the awaiting of the flip-chip packages in an oven. As a result, the filling 142, such as silicon dioxide powder, inside the underfill 140 is deposited as shown in FIG. 1. Furthermore, after the underfill 140 is curred, the composition in the underfill 140 is not uniformly distributed, which contributes inconsistent CTEs (coefficients of thermal expansion) inside the underfill 140 and triggers the flip-chip package to get failure caused by extreme thermal stress in a subsequent process or a reliability test

### SUMMARY OF THE INVENTION

Based on the above described, an object of the present invention is to provide a process of fabricating flip-chip packages, which is capable of avoiding filling deposition in underfill by means of the above-described method for forming underfill and enhancing the reliability of flip-chip packages.

The present invention further provides a process of fabricating flip-chip packages. First, a substrate having a carrying surface is provided. Next, a chip having an active surface is provided, on which a plurality of bonding pads are disposed. On each bonding pad, a bump is disposed. Afterwards, the active surface of the chip is placed to face the carrying surface of the substrate, so that the chip is electrically connected to the substrate via the bumps and a flip-chip package is formed. Further, an underfill is filled between the substrate and the chip, so that the underfill encapsulates the bumps. Then, the underfill is partially cured during a waiting time of the flip-chip packages, where the processing temperature is kept between 100° C. and 140° C. Furthermore, the underfill is fully cured by heating the same.

In the process of fabricating flip-chip packages provided by the present invention, after the chip is electrically connected to the substrate via the bumps and before the underfill is filled, the bumps may further be reflowed. Besides, after the chip is electrically connected to the substrate via the bumps and before the underfill is filled, a pre-heating step may be performed to the substrate and the chip. Besides, the above-described method for heating the underfill may include baking.

In the process of fabricating flip-chip packages and the method for forming underfill thereof, the processing temperature is kept between 100° C. and 140° C. after filling the underfill so that the underfill can be partially cured in assurance, which is able for avoiding filling deposition inside underfill and enhancing the reliability of flip-chip packages.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a schematic sectional view of a conventional flip-chip package.

FIG. 2 is a flowchart diagram of a flip-chip packaging process in the embodiment of the present invention.

FIG. 3A˜FIG. 3G are schematic sectional views showing the flip-chip packaging process in FIG. 2.

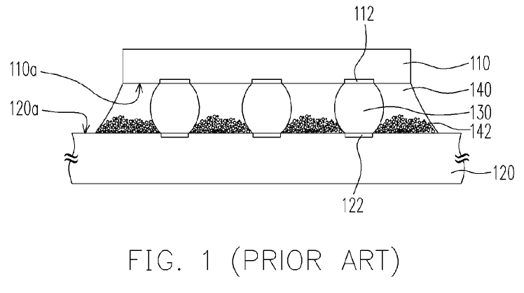

### DESCRIPTION OF THE EMBODIMENTS

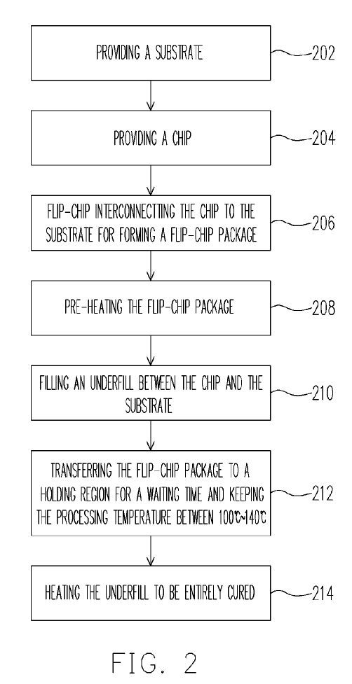

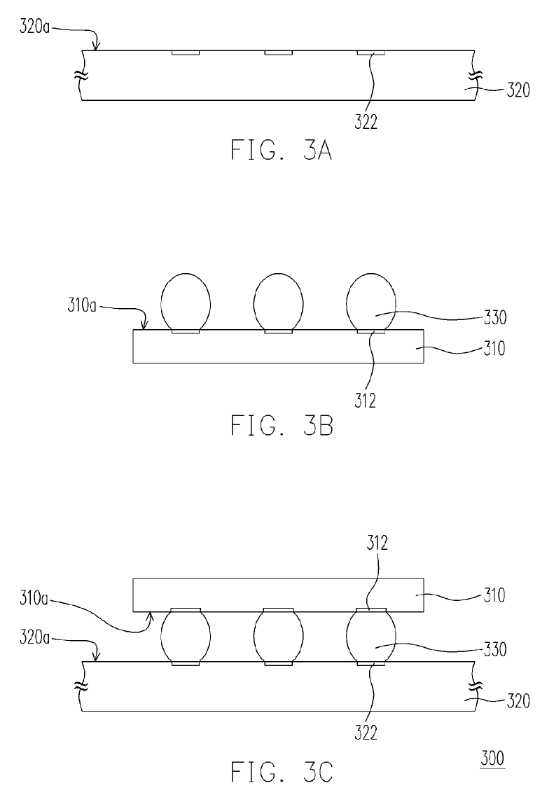

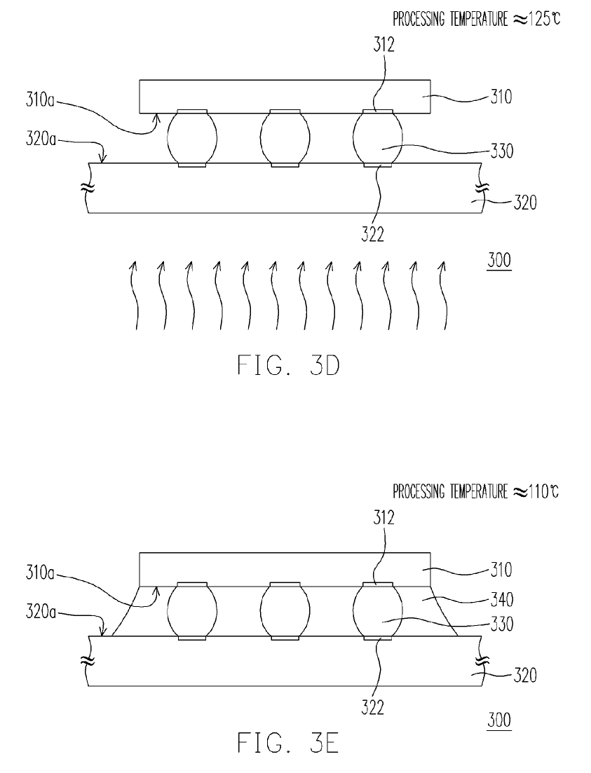

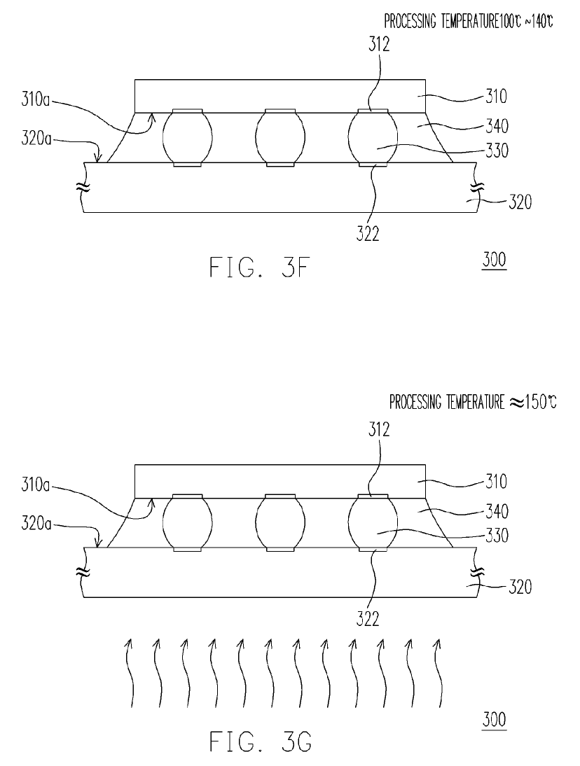

FIG. 2 is a flowchart diagram of a flip-chip packaging process in the embodiment of the present invention. FIG. 3A˜FIG. 3G are schematic section views showing the flip-chip packaging process in FIG. 2.

Referring to FIG. 3A, at step 202 first, a substrate 320 is provided, wherein the substrate 320 has a carrying surface 320a and a plurality of bump pads 322 disposed thereon. In the embodiment, the substrate 320 may be a useful printed circuit board (PCB), a ball grid array substrate (BGA substrate) or other types of carriers.

Referring to FIG. 3B, at step 204 next, a chip 310 is provided, wherein the chip 310 may have an active surface 310a and a plurality of bonding pads 312 corresponding to the bump pads 322 disposed thereon and on each bonding pad 312 a bump 330 is disposed. In the embodiment, the bumps 330 are solder bumps fabricated by means of a normal bumping process and the material of the bumps 330 is, for example, tin-lead alloy, tin-silver-copper alloy, tin-copper alloy or other soldering-friendly materials.

Afterwards at step 206, referring to FIG. 3C, the chip 310 and the substrate 320 are flip-chip interconnected to each other to form a flip-chip package 300, wherein the chip 310 is flipped so that the active surface 310a of the chip 310 faces a carrying surface 320a of the substrate 320, and then a step of reflow is performed to electrically connect the chip 310 to the bump pads 322 of the substrate 320 via the bumps 330.

Further at step 208, referring to FIG. 3D, the flip-chip package 300 may be pre-heated at a processing temperature of, for example, around 125° C., which is helpful to improve fluidity of the underfill 340 between the chip 310 and the substrate 320 during filling the underfill 340, as shown in FIG. 3E.

Furthermore at step 210, referring to FIG. 3E, an underfill 340 is filled between the chip 310 and the substrate 320, wherein the underfill 340 is, for example, a filler doped with silicon dioxide powder and the filler itself is, for example, epoxy resin. The processing temperature for filling the underfill 340 is, for example, around 110° C.

After that at step 212, referring to FIG. 3F, the flip-chip package 300 is transferred to a holding region (not shown in the figure) to wait for some time. The processing temperature in the holding region ranges between 100° C. and 140° C. In comparison with 80° C. of the prior art, the processing temperature range between 100° C. and 140° C. provided by the present invention is considerably higher herein and the underfill is accordingly, partially cured in assurance, which is able to effectively avoid deposition of the filler inside the underfill 340 during the waiting time.

In the end at step 214, referring to FIG. 3G, the underfill 340 is heated for fully curing. The method for heating the underfill 340 is, for example, baking the flip-chip packages of the same batch by means of an oven and the processing temperature is, for example, 150° C.

With the process of fabricating flip-chip packages and the method for forming underfill thereof, after filling the underfill, the processing temperature is kept between 100° C. and 140° C. for the underfill to be partially cured in assurance, which is able for effectively avoiding filling deposition inside underfill.

It should be noted that the processing temperatures at the above-described steps of, such as pre-heating, filling the underfill and curing the underfill, are considered as exemplary only. In other embodiments, the processing temperatures of the steps could be varied depending on the underfill kinds or the processing needs. To those skilled in the art, only if the processing temperature during the waiting time is kept between 100° C. and 140° C., other better processing parameters and an improved effect are expected to be achieved depending on the real needs without departing from the scope or spirit of the invention.

From the above described, it can be seen that by means of the process of fabricating flip-chip packages and the method for forming underfill provided by the present invention, the material uniformity after curing the underfill is solidly improved, which significantly enhances the reliability of flip-chip packages.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A process of fabricating flip-chip packages, comprising:
providing a substrate having a carrying surface;
providing a chip, wherein the chip has an active surface, a plurality of bonding pads are disposed on the active surface and each bonding pad has a bump thereon;
making the active surface of the chip face the carrying surface of the substrate, so that the chip is electrically connected to the substrate via the bumps;
filling an underfill between the substrate and the chip so that the underfill encapsulates the bumps;
keeping the processing temperature between 100° C. and 140° C. during a waiting time so that the underfill is partially cured; and
heating the underfill to fully cure the underfill.

2. The process of fabricating flip-chip packages as recited in claim 1, wherein, after electrically connecting the chip to the substrate via the bumps and before filling the underfill, the process further comprises reflowing the bumps.

3. The process of fabricating flip-chip packages as recited in claim 1, wherein, after electrically connecting the chip to the substrate via the bumps and before filling the underfill, the process further comprises a step of pre-heating the substrate and the chip.

4. The process of fabricating flip-chip packages as recited in claim 1, wherein the method for heating the underfill comprises baking.
